(19) United States
(12) Patent Application Publication
(10) Pub. No.: US 2008/0282982 A1
(43) Pub. Date: Nov. 20, 2008

(54) APPARATUS AND METHOD FOR DEPOSITION OVER LARGE AREA SUBSTRATES

(75) Inventors: John M. White, Hayward, CA (US); Sanjay Yadav, San Jose, CA (US); Qunhua Wang, San Jose, CA (US); Soo Young Choi, Fremont, CA (US); Weijie Wang, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: Applied Materials, Inc.

(21) Appl. No.: 12/039,613

(22) Filed: Feb. 28, 2008

Related U.S. Application Data
(60) Provisional application No. 60/892,231, filed on Feb. 28, 2007.

(51) Int. Cl. C23C 16/50

(52) U.S. Cl. 118/723 R; 118/58

(57) ABSTRACT

The present invention generally relates to an inductively coupled plasma apparatus. When depositing utilizing a plasma generated from a showerhead, the plasma may not be evenly distributed to the edge of the substrate. By inductively coupling plasma to the chamber in an area corresponding to the chamber walls, the plasma distribution within the chamber may be evenly distributed and deposition upon the substrate may be substantially even. By vaporizing the processing gas prior to entry into the processing chamber, the plasma may also be even and thus contribute to an even deposition on the substrate.

### CROSS-REFERENCE TO RELATED APPLICATIONS

This application claims benefit of U.S. Provisional Patent Application Ser. No. 60/892,231 (APPM/11914L), entitled, “Apparatus and Method for Deposition Over Large Area Substrates”, filed Feb. 28, 2007, which is herein incorporated by reference.

### BACKGROUND OF THE INVENTION

1. Field of the Invention

Embodiments of the present invention generally relate to an inductively coupled plasma apparatus.

2. Description of the Related Art

In the fabrication of flat panel displays (FPD), thin film transistors (TFT) and liquid crystal displays (LCDs), metal interconnects, solar panels, and other features are formed by depositing and removing multiple layers of conducting, semiconducting and dielectric materials on a glass substrate. The various features formed are integrated into a system that collectively is used to create, for example, active matrix display screens in which display states are electrically created in individual pixels on the FPD. Processing techniques used to create the FPD include plasma-enhanced chemical vapor deposition (PECVD), physical vapor deposition (PVD), etching, and the like. Plasma processing is particularly well suited for the production of flat panel displays because of the relatively lower processing temperatures that may be used to deposit films and the good film quality which results. Therefore, there is a need in the art for an apparatus to deposit layers onto substrates for fabrication of FPDs, TFTs, LCDs, metal interconnects, solar panels, and other features.

### SUMMARY OF THE INVENTION

The present invention generally relates to an inductively coupled plasma apparatus. When depositing utilizing a plasma generated from a showerhead, the plasma may not be evenly distributed to the edge of the substrate. By inductively coupling plasma to the chamber in an area corresponding to the chamber walls, the plasma distribution within the chamber may be evenly distributed and deposition upon the substrate may be substantially even. By vaporizing the processing gas prior to entry into the processing chamber, the plasma may also be even and thus contribute to an even deposition on the substrate.

In one embodiment, an apparatus comprises a chamber body having a plurality of chamber walls, a substrate support, a gas distribution assembly, and an inductively coupled plasma source coupled with one or more of the plurality of chamber walls. The inductively coupled plasma source may comprise a metal containing coil encapsulated in a non-metallic material.

In another embodiment, a vaporizer comprises a vaporizer body having a first section and a second section. Each section extends to a first height. The first section has a plurality of plenums coupled together by a plurality of passages extending perpendicular to the plurality of plenums. A topmost plenum of the first section may be coupled with a bottommost plenum of the second section. The second section may have a plurality of plenums coupled together by a plurality of passages extending perpendicular to a plurality of gas passages.

In another embodiment, an apparatus comprises a chamber body, a gas distribution showerhead coupled with the chamber body, a substrate support disposed in the chamber body opposite to the gas distribution showerhead, an inductively coupled plasma source coupled with the chamber body, and a vaporizer coupled with the gas distribution showerhead. The vaporizer may comprise a vaporizer body having a plurality of plenums connected by a plurality of passages. The passages may be arranged substantially perpendicular to the plurality of plenums. The inductively coupled plasma source may have a polytetrafluoro ethylene outer surface. The inductively coupled plasma source may substantially surround a processing area between the gas distribution showerhead and the substrate support.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a plasma process chamber according to one embodiment of the invention.

FIG. 2 is a cross sectional view of an inductively coupled plasma source according to one embodiment of the invention.

FIG. 3 is a cross sectional view of an inductively coupled plasma source according to another embodiment of the invention.

FIG. 4A is a cross sectional view of a vaporizer according to one embodiment of the invention.

FIG. 4B is a top cross sectional view of the vaporizer of FIG. 4A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present invention generally relates to an inductively coupled plasma apparatus. When depositing utilizing a plasma generated from a showerhead, the plasma may not be evenly distributed to the edge of the substrate. By inductively coupling plasma to the chamber in an area corresponding to the chamber walls, the plasma distribution within the chamber may be evenly distributed and deposition upon the substrate may be substantially even. By vaporizing the processing gas prior to entry into the processing chamber, the plasma may also be even and thus contribute to an even deposition on the substrate. The invention is illustratively described below in reference to a chemical vapor deposition system, processing large area substrates, such as a plasma enhanced chemical vapor deposition (PECVD) system, available from AKT, a division of Applied Materials, Inc., Santa Clara, Calif. However, it should be understood that the apparatus and method may have utility in other system configurations, including those systems configured to process round substrates.

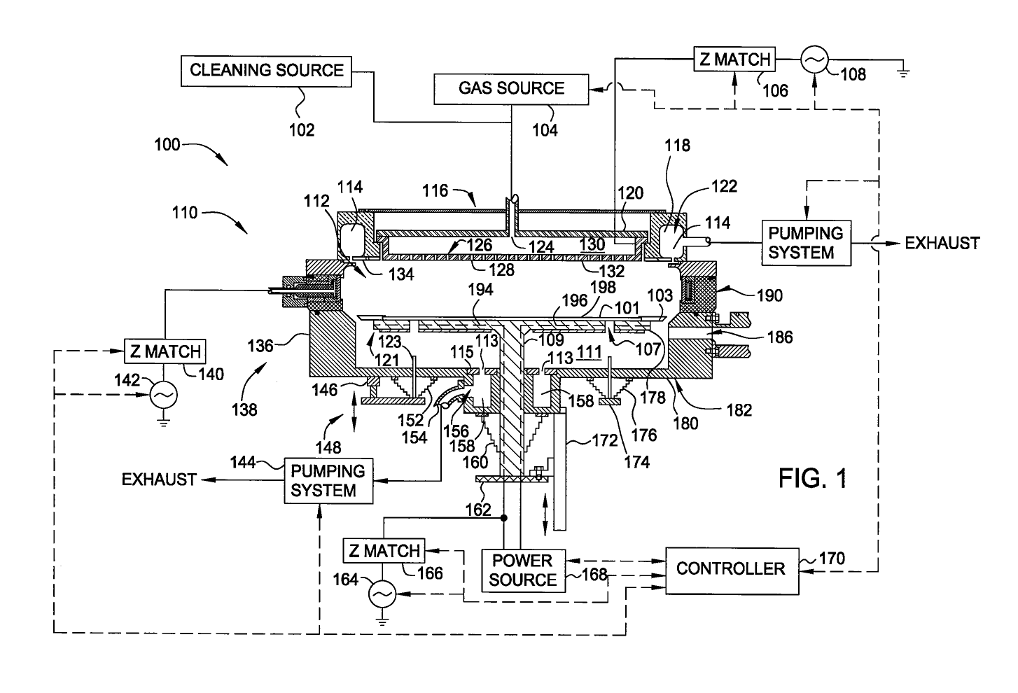

FIG. 1 is a schematic cross-sectional view of a plasma processing chamber 100. The plasma processing chamber 100 generally includes a gas distribution assembly 132, an inductively coupled source assembly 110, and a lower chamber assembly 138. A chamber volume 112, which is made up of an process volume and a lower volume 111, defines a region in which the plasma processing will occur in the plasma processing chamber 100 and is enclosed by the gas distribution assembly 132, the inductively coupled source assembly 110, and the lower chamber assembly 138.

The lower chamber assembly 138 generally includes a substrate lift assembly 148, a substrate support 107 and a processing chamber base 182. The processing chamber base 182 has chamber walls 136 and a chamber bottom 180 that partially define a lower volume 111. The processing chamber base 182 is accessed through the access port 186 in the chamber walls 136. The access port 186 defines the region through which a substrate 101 can be moved in and out of the processing chamber base 182. The chamber walls 136 and chamber bottom 180 may be fabricated from a unitary block of aluminum or other material(s) compatible with processing.

A temperature controlled substrate support 196 is connected to the processing chamber base 182. The substrate support 196 supports a substrate 101 during processing. In one embodiment, the substrate support 196 comprises an aluminum body 121 that encapsulates at least one embedded heater 194. The embedded heater 194, such as a resistive heating element, is disposed in the substrate support 196. The embedded heater 194 is coupled to a power source 168, which can controllably heat the substrate support 196 and the substrate 101 positioned thereon to a predetermined temperature by use of a controller 170. Typically, in most CVD processes, the embedded heater 194 maintains the substrate 101 at a uniform temperature range between about 60 degrees Celsius for plastic substrates to about 550 degrees Celsius for glass substrates.

Generally, the substrate support 196 has a back side 178, a front side and a stem 109. The front side supports the substrate 101, while the stem 109 is coupled to the back side 178. The stem base 162 attached to the stem 109 is connected to a lift assembly 172 that moves the substrate support 196 between various positions. The transfer position, allows the system robot (not shown) to freely enter and exit the plasma processing chamber 100 without interference with the substrate support 196 and/or the lift pins 123. The stem 109 additionally provides a conduit for electrical and thermocouple leads between the substrate support 196 and other components of the cluster tool. The lift assembly 172 may comprise a pneumatic or motorized lead-screw type lift assembly commonly used in the art to supply the force necessary to counteract gravity and atmospheric pressure forces acting on the substrate support 196 when the plasma processing chamber 100 is under vacuum, and to accurately position the support assembly in the plasma processing chamber 100.

A bellows 160 is coupled between substrate support 196 (or the stem 109) and the chamber bottom 180 of the processing chamber base 182. The bellows 160 provides a vacuum seal between the chamber volume 112 and the atmosphere outside the processing chamber base 182, while facilitating vertical movement of the substrate support 196.

The substrate support 196 additionally supports a substrate 101 and a circumscribing shadow frame 103. Generally, the shadow frame 103 prevents deposition on the edge of the substrate 101 and on the substrate support 196. In one embodiment the shadow frame 103 is separated from the substrate 101 and the substrate support 196 by use of a feature attached to the substrate lift assembly 148 (not shown). In another embodiment the shadow frame 103 is deposited on a capturing feature (not shown), which is mounted in the plasma processing chamber 100, as the substrate support moves down from the processing position, to allow the substrate support 196 to separate from the shadow frame 103 as it rests on the capture feature. The capture feature embodiment or the feature attached to the substrate lift assembly embodiment will thus help facilitate the removal of the substrate 101 from the substrate support 196 and thus the plasma processing chamber 100.

The substrate support 196 has a plurality of holes 107 disposed therethrough to accept a plurality of lift pins 120. The lift pins 120 are typically made from ceramic, graphite, ceramic coated metal, or stainless steel. The lift pins 120 may be actuated relative to the substrate support 196 and process chamber base 182 by use of a lift plate 174, that can move the lift pins 120 from a retracted position to a raised position. The lift bellows 176, 152 attached to each of the lift pins 120 and the chamber bottom 180, are used to isolate the lower volume 111 from the atmosphere outside of the plasma process chamber 100, while also allowing the lift pins 120 to move from the retracted position to the raised position. The lift plate 174 is actuated by use of a lift actuator 146. When the lift pins 120 are in the raised position and the substrate support 196 is in the transfer position the substrate 101 is lifted above the top edge of the access port 186 so that the system robot can enter and exit from the plasma processing chamber 100.

The lid assembly 116 typically includes an entry port 124 through which process gases, provided by the gas source 104, are introduced into the process volume after passing through the gas distribution plate 132. Proper control and regulation of the gas flows from the gas source 104 to the entry port 124 are performed by mass flow controllers (not shown) and a controller 170. The gas source 104 may include a plurality of mass flow controllers (not shown). The term “mass flow controllers”, as used herein, refers to any control valves capable of providing rapid and precise gas flow to the plasma processing chamber 100. The entry port 124 allows process gases to be introduced and uniformly distributed in the plasma processing chamber 100. Additionally, the entry port 124 may optionally be heated to prevent condensation of any reactive gases within the manifold. The gas source 104 may comprise a vaporizer (not shown).

The entry port 124 is also coupled to a cleaning source 102. The cleaning source 102 typically provides a cleaning agent, such as disassociated fluorine, that is introduced into the process volume to remove deposition by-products and stray deposited material left over after the completion of prior processing steps.

The lid assembly 116 provides an upper boundary to the process volume. The lid assembly 116 typically can be removed from the chamber base 182 and/or the inductively coupled source assembly 110 to service components in the plasma processing chamber 100. Typically, the lid assembly 116 is fabricated from aluminum (Al) or an anodized aluminum body.

In one embodiment the lid assembly 116 includes a pumping plenum 118 which is coupled to an external vacuum pumping system. The pumping plenum 118 is utilized to uniformly evacuate the gases and processing by-products from the process volume. The pumping plenum 118 is generally formed within, or attached to, the chamber lid 122 and covered by a plate to form the pumping channel 114. To assure uniform evacuation of the process volume a gap is formed between the plate and chamber lid 122, to create a small restriction 134 to gas flow into the pumping channel 114. In one embodiment a shadow feature formed on the lid support member of the inductively coupled source assembly 110 may also be used to supply an additional restriction to further assure uniform evacuation of the process volume. The vacuum pumping system will generally contain a vacuum pump which may be a turbo pump, rough pump, and/or Roots Blower™ as required to achieve the desired chamber processing pressures.

In another embodiment a pumping plenum 156, found in the lower chamber assembly 138, is used to uniformly evacuate the gases and processing by-products from the process volume by use of a vacuum pumping system 144. The pumping plenum 156 is generally formed within, or attached to, the chamber bottom 180 and that may be covered by a plate 115 to form a enclosed pumping channel 158. The plate generally contains a plurality of holes 113 (or slots) to create a small restriction to gas flow into the pumping channel 158 to assure uniform evacuation of the chamber volume 112. The pumping channel 158 is connected to the vacuum pumping system 144 through a pumping port 154. The vacuum pumping system 144 generally contains a vacuum pump which may be a turbo pump, rough pump, and/or Roots Blower™ as required to achieve the desired chamber processing pressures. In one embodiment, the pumping plenum 156 is symmetrically distributed about the center of the processing chamber to ensure even gas evacuation from the process volume. In another embodiment the pumping plenum 156 is non-symmetrically positioned (not shown) in the lower chamber assembly 138.

In another embodiment a pumping plenum 156 and a pumping plenum 114 are both used to evacuate the process volume. In this embodiment the relative flow rate of gas removed from the process volume, by use of vacuum pumping system, and from the lower volume 111, by use of vacuum pumping system 144, may be optimized to improve plasma processing results and reduce the leakage of the plasma and processing by-products into the lower volume 111. Reducing the leakage of the plasma and processing by-products will reduce the amount of stray deposition on the lower chamber assembly 138 components and thus reduce the clean time and/or the frequency of using the cleaning source 102 to remove these unwanted deposits.

A gas distribution plate 132 is coupled to a top plate 120 of the lid assembly 116. The shape of the gas distribution plate 132 is typically configured to substantially follow the profile of the substrate 101. The gas distribution plate 132 includes a perforated area 126, through which process and other gases supplied from the gas source 104 are delivered to the process volume. The perforated area 126 of the gas distribution plate 132 is configured to provide uniform distribution of gases passing through the gas distribution plate 132 into the process volume.

The gas distribution plate 132 may be formed from a single unitary member. In other embodiments the gas distribution plate 132 can be made from two or more separate pieces. A plurality of gas passages 128 are formed through the gas distribution plate 132 to allow a desired distribution of the process gases to pass through the gas distribution plate 132 and into the process volume. A plenum 130 is formed between the gas distribution plate 132 and the top plate 120. The plenum 130 allows gases flowing into the plenum 130 from the gas source 104 to uniformly distribute across the width of the gas distribution plate 132 and flow uniformly through the gas passages 128. The gas distribution plate 132 is typically fabricated from aluminum (Al), anodized aluminum, or other RF conductive material. The gas distribution plate 132 is electrically isolated from the chamber lid 122 by an electrical insulation piece (note shown).

In one embodiment the gas distribution plate 132 is RF biased so that a plasma generated in the process volume can be controlled and shaped by use of an attached impedance match element 106, an RF power source 108 and the controller 170. The RF biased gas distribution plate 132 acts as a capacitively coupled RF energy transmitting device that can generate and control the plasma in the process volume.

In another embodiment an RF power source 164 applies RF bias power to the substrate support 196 through an impedance match element 166. By use of the RF power source 164, the impedance match element 166 and the controller 170 the user can control the generated plasma in the process volume, control plasma bombardment of the substrate 101 and vary the plasma sheath thickness over the substrate surface 198. In another embodiment, the RF power source 164 and the impedance match element 166 are replaced by one or more connections to ground (not shown) thus grounding the substrate support 196.

To provide additional plasma control, an inductively coupled plasma source 190 may be coupled with the chamber. The inductively coupled plasma source 190 may be coupled to an RF power source 142 through an impedance match 140. The inductively coupled plasma source 190 may be disposed between the gas distribution plate 132 and the substrate 101. In one embodiment, the inductively coupled plasma source 190 may be disposed within the chamber walls. The inductively coupled plasma source 190 substantially evens out the plasma in the processing chamber by providing a plasma near the edge of the substrate 101.

To control the plasma processing chamber 100, process variables and components, along with the other cluster tool components, a controller 170 is adapted to control all aspects of the complete substrate processing sequence. The controller 170 is adapted to control the impedance match elements (i.e., 106, 166, and 140), the RF power sources (i.e., 108, 164 and 142) and all other elements of the plasma processing chamber 100. The plasma processing chamber's 100 plasma processing variables are controlled by use of a controller 170, which is typically a microprocessor-based controller. The controller 170 is configured to receive inputs from a user and/or various sensors in the plasma processing chamber and appropriately control the plasma processing chamber components in accordance with the various inputs and software instructions retained in the controller's memory. The controller 170 generally contains memory and a CPU which are utilized by the controller to retain various programs, process the programs, and execute the programs when necessary. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like all well known in the art. A program (or computer instructions) readable by the controller 170 determines which tasks are performable in the plasma processing chamber. Preferably, the program is software readable by the controller 170 and includes instructions to monitor and control the plasma process based on defined rules and input data.

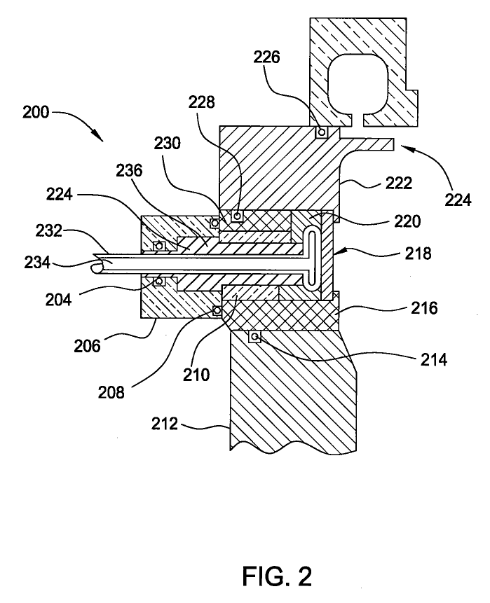

Referring to FIG. 2, an inductively coupled source assembly generally contains a RF coil 202, a support structure 200, a cover 218, and various insulating pieces (e.g., an inner insulation 220, an outer insulation 210, etc.) The inductively coupled source assembly may be shielded from an evacuation plenum by a shadow element 224. The supporting structure 200 generally contains an supporting member 230, the chamber walls 212, and a lower supporting member 216 and a lid support member 222, which are grounded metal parts which support the lid assembly's components. The RF coil 202 is supported and surrounded by a number of components which prevent the RF power delivered to the coil from the RF power source from arcing to the support structure 200 or incurring significant losses to the grounded chamber components (e.g., processing chamber base, etc.). A cover 218, which is a thin continuous ring, band or array of overlapping sections is attached to the supporting structure 200 components. The cover 218 is intended to shield the RF coil 202 from interacting with the plasma deposition chemistries or from being bombarded by ions or neutrals generated during plasma processing or by chamber cleaning chemistries. The cover 218 may be made from a ceramic material (e.g., alumina or sapphire) or other process-compatible dielectric material. In one embodiment, the cover 218 comprises polytetrafluoro ethylene. The cover 218 may comprise a tongue and groove construction. Also, various insulating pieces, for example, the inner insulation 220 and the outer insulation 210, are used to support and isolate the RF coil 202 from the electrically grounded supporting structure 200. The insulating pieces are generally made from an electrically insulating materials, for example, Teflon or ceramic materials. A vacuum feedthrough 206 attaches to the supporting structure 200 to hold and support the RF coil 202 and prevent atmospheric leakage into an evacuated process volume. The supporting structure 200, the vacuum feedthrough 206 and the various o-rings 226, 228, 214, 208 and 204 form a vacuum tight structure that supports the RF coil 202 and the gas distribution assembly, and allows the RF coil 202 to communicate with the process volume with no conductive barriers to inhibit the RF generated fields.

The RF coil 202, as shown in FIG. 2, is connected to a RF power sources through RF impedance match networks. In this configuration the RF coil 202 acts as an inductively coupled RF energy transmitting device that can generate and control the plasma generated in the process volume. In one embodiment, dynamic impedance matching may be provided to the RF coil 202. By use of the controller, the RF coil 202, which is mounted at the periphery of the process volume, is able to control and shape a plasma generated near the substrate surface. In one embodiment the RF coil 202, shown in FIG. 2, is a single turn coil used to control a plasma generated in the chamber volume. In another embodiment a multi-turn coil is used to control the plasma shape and density.

In some configurations the coil ends of a single turn coil can affect the uniformity of the plasma generated in the plasma processing chamber. When it is not practical or desired to overlap the ends of the coil, a gap region, may be left between the coil ends. The gap region, due to the missing length of coil and RF voltage interaction at the input end and output end of the coil, will result in weaker RF generated magnetic field near the gap. The weaker magnetic field in this region can have a negative effect on the plasma uniformity in the chamber. To resolve this possible problem, the reactance between the RF coil 202 and ground can be continuously or repeatedly tuned during processing by use of a variable inductor, which shifts or rotates the RF voltage distribution, and thus the generated plasma, along the RF coil 202, to time average any plasma non-uniformity and reduce the RF voltage interaction at the ends of the coil. As a consequence, the plasma generated in the process volume is more uniformly and axially symmetrically controlled, through time-averaging of the plasma distribution by varying the RF voltage distribution. The RF voltage distributions along the RF coil 202 can influence various properties of the plasma including the plasma density, RF potential profiles, and ion bombardment of the plasma-exposed surfaces including the substrate.

The RF coil 202 may comprise an inner passage 234 surrounded by the inner frame 232. In one embodiment, the inner frame 232 may comprise a metal containing material. In another embodiment, the inner frame 232 may comprise ceramic. The inner frame 232 may be substantially entirely encapsulated by an encapsulating member 236. The encapsulating member 236 may substantially enclose the inner frame 232 such that no processing gas may reach the inner frame 232. In one embodiment, the encapsulating member 236 may comprise polytetrafluoro ethylene. The encapsulating member 236 may abut the cover 218, the outer insulation 210, the supporting member 230, and the vacuum feedthrough 206 such that no space is present between the encapsulating member 236 and the cover 218, the outer insulation 210, the supporting member 230, and the vacuum feedthrough 206. In one embodiment, the encapsulating member 236 may be spaced from the cover 218, the outer insulation 210, the supporting member 230, and the vacuum feedthrough 206 by a distance less than the dark space. Process gases may seep into the area encompassed by the RF coil 202 and could ignite into a plasma. Thus, maintaining either no distance or a distance less than the dark space between the RF coil 202 and the cover 218, the outer insulation 210, the supporting member 230, and the vacuum feedthrough 206 may be beneficial.

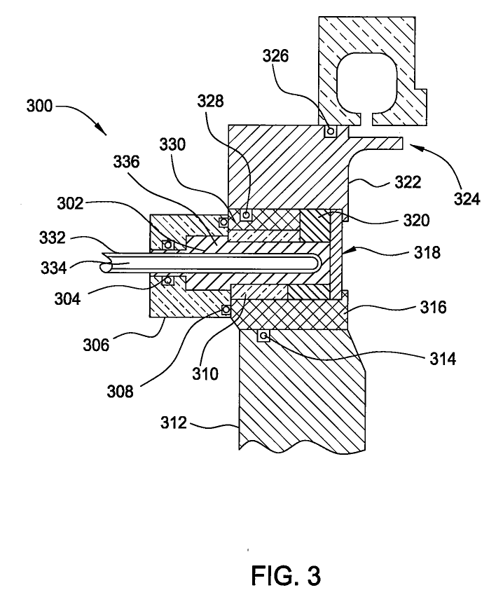

FIG. 3 is a cross sectional view of an inductively coupled plasma source according to another embodiment of the invention. Similar to FIG. 2, the inductively coupled plasma source comprises a support structure 300, outer cover 302, O-rings 304, 314, 308, 326, 328, vacuum feedthrough 306, outer insulation 310, chamber wall 312, supporting member 316, cover 318, inner insulation 320, support member 322, shadow element 322, and supporting member 330. The RF coil 302, however, has a tubular cross section. The RF coil 302 comprises a passage 334, inner frame 332, and encapsulating member 336 similar to that discussed above in relation to FIG. 2.

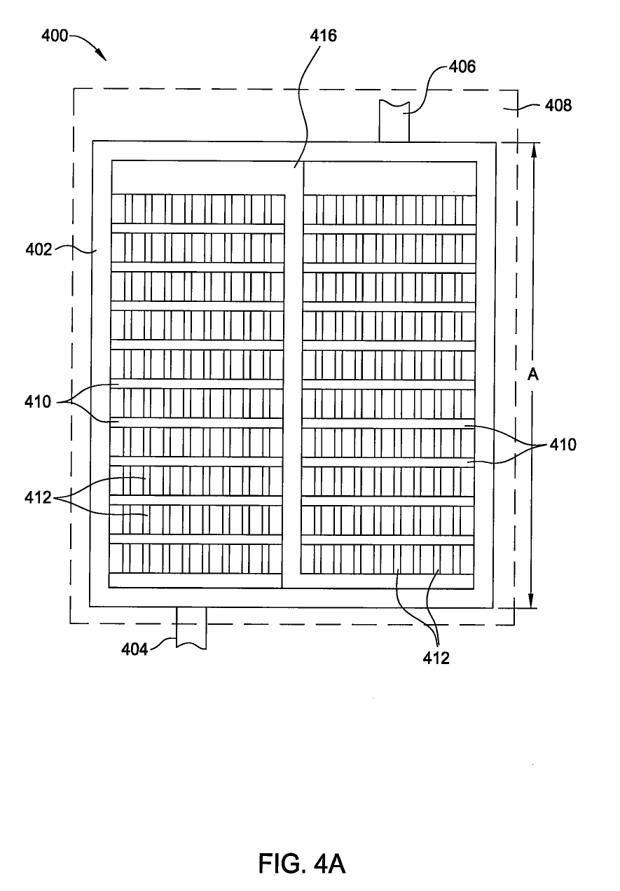

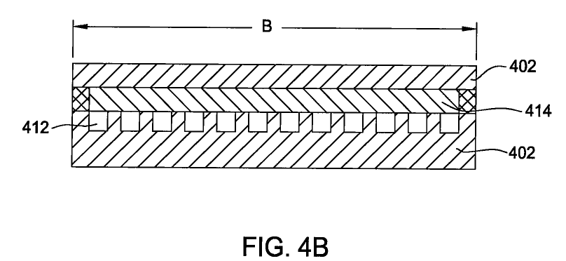

FIG. 4A is a cross sectional view of a vaporizer 400 according to one embodiment of the invention. FIG. 4B is a top cross sectional view of the vaporizer 400 of FIG. 4A. The vaporizer 400 may comprise a plurality of walls 402 that enclose the vaporizing area. The vaporizer 400 may have a height shown by arrows “A” and a width shown by arrows “B”. In one embodiment, the height of the vaporizer 400 may be between about 3 inches to about 10 inches. In one embodiment, the width of the vaporizer 400 may be between about 1 inch and about 5 inches.

Liquid precursor may enter the vaporizer 400 through an inlet 404 and flow into a plenum 410 for even distribution into a plurality of gas passages 412. The passages 412 may be formed into the chamber walls 402 and covered with a cover 414 that may be welded to the chamber walls 402 to seal the passages 412. The liquid precursor vaporizes within the vaporizer 400 as it flows through the vaporizer 400 and is heated by the heater assembly 408. The vapor is pulled through the vaporizer 400 by the vacuum draw of the vacuum processing chamber. The vapor exits the vaporizer through an outlet 406. The entire vaporizer 400 may be enclosed in a heater assembly 408. The vaporizer 400 may comprise a plurality of sections 418, 420. It is to be understood that while two sections 418, 420 have been shown, more sections 418, 420 may be present.

The two sections 418, 420 may be disposed substantially in parallel with each other. The liquid precursor enters the first section 418 through the inlet 404. The liquid precursor then flows into a first plenum where it spreads out before entering into a plurality of passages 412. The passages 412 connect with another plenum 412 which connects with another plurality of passages 412. In one embodiment, the number of plenums 410 in the first section 418 may be greater than about five plenums. In another embodiment, the number of plenums in the first section 418 may be greater than about ten plenums. In one embodiment, the number of passages 412 between two plenums 410 may comprise between about ten passages 412 and about sixty passages 412.

The second section 420 may be substantially identical to the first section 418. The top of the first section 418 may be directly coupled to the bottom of the second section 420 by a single passage 416 such that the vapor and/or liquid precursor flows in a direction substantially opposite to the flow through the passages 412 in the first section 418. The single passage 416 may be directly coupled between a plenum 410 of the first section 418 and a plenum of the second section 420. While only a single passage 416 is shown, it is to be understood that more passages 416 may be present in which the liquid precursor and/or vapor is caused to flow in a direction substantially opposite to the flow through the passages 412 in the first section 418.

The liquid precursor and/or vapor flows through the second section 420 in a manner similar to the first section 418. The vapor exits the vaporizer 400 through the second section 420 at an outlet 406 where the vapor may be co-flowed with helium to the processing chamber.

The vapor provided to the chamber by the vaporizer 400 may be consistent on a substrate to substrate basis. Because the liquid precursor and/or vapor flows through a plurality of sections 418, 420, the residence time of the liquid precursor within the vaporizer 400 is increased such that the liquid precursor sufficiently vaporizes and flows out of the vaporizer 400 at a consistent, predictable pressure. The consistent, predictable pressure reduces deposition irregularities caused by pressure fluxuations that may occur if the liquid precursor is not fully vaporized. If the pressure is not consistent and predictable leaving the vaporizer 400, then the deposition rate in the processing chamber may fluxuate on a substrate to substrate basis.

By inductively coupling plasma to a processing chamber, plasma may be evenly distributed within the processing chamber. A vaporizer coupled to the processing chamber may deliver processing gas to the processing chamber consistently on a substrate to substrate basis.

While the foregoing is directed to embodiments of the present invention, other and further embodiments of the invention may be devised without departing from the basic scope thereof, and the scope thereof is determined by the claims that follow.

1. An apparatus, comprising:
a chamber body having a plurality of chamber walls;
a substrate support;
a gas distribution assembly;
an inductively coupled plasma source coupled with one or more of the plurality of chamber walls, the inductively coupled plasma source comprising a metal containing coil encapsulated in a non-metallic material; and
a dielectric cover abutting the encapsulated metal containing coil.

2. The apparatus of claim 1, wherein the non-metallic material comprises polytetrafluoro ethylene.

3. The apparatus of claim 2, wherein the metal containing coil comprises a ceramic material.

4. The apparatus of claim 1, further comprising a vaporizer coupled with the chamber body, the vaporizer comprising:
a vaporizer body having a first section and a second section each extending to a first height, the first section having a plurality of plenums coupled together by a plurality of passages extending perpendicular to the plurality of plenums, a topmost plenum of the first section directly coupled with a bottommost plenum of the second section, the second section having a plurality of plenums coupled together by a plurality of passages extending perpendicular to a plurality of gas passages.

5. The apparatus of claim 4, wherein the vaporizer body is enclosed by a heat exchanging assembly.

6. The apparatus of claim 4, wherein two plenums are coupled together by a number of passages between about 10 passages and about 50 passages.

7. The apparatus of claim 6, wherein the passages coupled between a first two plenums are substantially aligned with the passages coupled between a second two plenums different than the first two plenums.

8. The apparatus of claim 1, wherein the cover is disposed between the inductively coupled plasma source and a processing area, wherein the cover is coupled with one or more chamber walls.

9. The apparatus of claim 1, wherein the inductively coupled plasma source comprises a substantially tubular shape and extends substantially around the chamber body.

10. The apparatus of claim 9, wherein the inductively coupled plasma source has a diameter between about one half inch to about one and one half inches.

11. A vaporizer, comprising:
a vaporizer body having a first section and a second section each extending to a first height, the first section having a plurality of plenums coupled together by a plurality of passages extending perpendicular to the plurality of plenums, a topmost plenum of the first section coupled with a bottommost plenum of the second section, the second section having a plurality of plenums coupled together by a plurality of passages extending perpendicular to a plurality of gas passages.

12. The vaporizer of claim 11, wherein the vaporizer body is enclosed by a heat exchanging assembly.

13. The vaporizer of claim 11, wherein two plenums are coupled together by a number of passages between about 10 passages and about 50 passages.

14. The vaporizer of claim 11, wherein the passages coupled between a first two plenums are substantially aligned with the passages coupled between a second two plenums different than the first two plenums.

15. An apparatus, comprising:
a chamber body;
a gas distribution showerhead coupled with the chamber body;
a substrate support disposed in the chamber body opposite to the gas distribution showerhead;
an inductively coupled plasma source coupled with the chamber body and substantially surrounding a processing area between the gas distribution showerhead and the substrate support, the inductively coupled plasma source having a polytetrafluoro ethylene outer surface; and
a vaporizer coupled with the gas distribution showerhead, the vaporizer comprising a vaporizer body having a plurality of plenums connected by a plurality of passages, the passages arranged substantially perpendicular to the plurality of plenums.

16. The apparatus of claim 15, wherein the polytetrafluoro ethylene encapsulates a ceramic material.

17. The apparatus of claim 15, further comprising a panel coupled with the chamber body and disposed between the processing area and the inductively coupled plasma source.

18. The apparatus of claim 17, wherein the panel comprises quartz.

19. The apparatus of claim 17, wherein the vaporizer further comprises a plurality of substantially identical sections and wherein each section comprises a plurality of plenums connected by a plurality of gas passages arranged substantially perpendicular to the plurality of plenums, and wherein at least one plenum of at least one section is directly coupled to at least one plenum of another section.

20. The apparatus of claim 19, wherein the at least one plenum of at least one section is directly coupled to at least one plenum of another section by a single gas passage.
